(19) United States
(12) Patent Application Publication
(10) Pub. No.: US 2008/0061314 A1
(43) Pub. Date: Mar. 13, 2008

(54) LIGHT EMITTING DEVICE WITH HIGH HEAT-DISSIPATING CAPABILITY

(76) Inventors: Tsung-Jen Liaw, Taipei Hsien (TW); Yen-Cheng Chen, Taipei Hsien (TW); Ming-Li Chang, Taipei Hsien (TW); Chung-Kai Wang, Taipei Hsien (TW); Ching-Lin Tseng, Taipei Hsien (TW)

Correspondence Address: CHRISTIE, PARKER & HALE, LLP, PO BOX 7068, PASADENA, CA, 91109-7068, US

(21) Appl. No.: 11/852,962

(22) Filed: Sep. 10, 2007

(30) Foreign Application Priority Data
Sep. 13, 2006 (TW) 095133826

(51) Int. Cl. H01L 33/00

(52) U.S. Cl. 257/99; 257/E33.058

(57) ABSTRACT

A light emitting device includes: a heat dissipating unit including a metallic first heat sink having a chip-mounting area, a thermally conductive bonding layer, and a metallic second heat sink overlapping and attached to the first heat sink through the bonding layer such that the bonding layer is sandwiched between the first and second heat sinks, the heat dissipating unit being formed with a light exit window that is aligned with the chip-mounting area and that extends through the second heat sink and the bonding layer so as to expose the chip-mounting area; a light emitting chip attached to the chip-mounting area of the first heat sink for emitting light through the light exit window; and a transparent enclosing material filling the light exit window to enclose the light emitting chip.

### CROSS-REFERENCE TO RELATED APPLICATION

This application claims priority of Taiwanese Application No. 095133826, filed on Sep. 13, 2006.

### BACKGROUND OF THE INVENTION

1. Field of the Invention

The invention relates to a light emitting device, more particularly to a light emitting device including a pair of overlapping heat sinks and a light emitting chip disposed on one of the heat sinks for emitting light through a window formed in the other of the heat sinks.

2. Description of the Related Art

Semiconductor light emitting diodes (LEDs) are among the most efficient sources currently available. Due to the requirement in high light output for the lighting application, the size of the LED chips becomes larger, and the applied current for the LED chips is considerably increased to a relatively high level. High power LEDs have become popular in recent years. However, the light efficiency of commercial LEDs, particularly for the white light LEDs, is only about 20-40%, and about 60-80% of the electrical power applied to the LEDs is transformed into heat, which can result in an increase in the temperature of the LEDs, which, in turn, can result in a reduction in the performance and the service life of the LEDs. Hence, heat dissipation has become a major task for development of the LEDs in the lighting application.

U.S. Pat. No. 6,274,924 discloses an LED package including a heat-sinking slug that is inserted into an insert-molded leadframe. An LED die is seated on the slug that is made from a high thermal conductive material, such as copper or aluminum. However, the slug is confined tightly by a molded plastic material, which has a poor thermal conductivity, and only a bottom of the slug is exposed from the molded plastic material. Hence, the heat dissipation efficiency of the LED die is relatively poor.

U.S. Pat. No. 6,498,355 discloses an LED package for high flux application. A metal core printed circuit board (MCPCB) is incorporated into the LED package to absorb heat resulting from the LED die through vias and a thermal conductive material. A flip-chip type of the LED is used so as to reduce the thermal impedance between the light emitting junction of the LED die and a metal substrate of the MCPCB. However, since most of an upper surface of the metal substrate of the MCPCB is covered by a dielectric layer, which has a poor thermal conductivity, the thermal dissipation efficiency of the LED package is also poor.

### SUMMARY OF THE INVENTION

Therefore, the object of the present invention is to provide a light emitting device that can overcome the aforesaid drawback associated with the prior art.

Accordingly, a light emitting device of the present invention comprises: a heat dissipating unit including a metallic first heat sink having a chip-mounting area, a thermally conductive bonding layer, and a metallic second heat sink overlapping and attached to the first heat sink through the bonding layer such that the bonding layer is sandwiched between the first and second heat sinks, the heat dissipating unit being formed with at least one light exit window that is aligned with the chip-mounting area and that extends through the second heat sink and the bonding layer so as to expose the chip-mounting area; at least one light emitting chip attached to the chip-mounting area of the first heat sink for emitting light through the light exit window; at least one pair of electrically conductive terminals, each of which is coupled electrically to said light emitting chip and each of which has an insulated portion that is disposed between said first and second heat sinks and that extends outwardly beyond peripheral ends of said first and second heat sinks; and a transparent enclosing material filling the light exit window to enclose the light emitting chip.

### BRIEF DESCRIPTION OF THE DRAWINGS

Other features and advantages of the present invention will become apparent in the following detailed description of the preferred embodiments with reference to the accompanying drawings, of which:

FIG. 1 is an assembled perspective view of the first preferred embodiment of a light emitting device according to the present invention;

FIG. 2 is a sectional view of the first preferred embodiment;

FIG. 3 is an assembled perspective view of the second preferred embodiment of the light emitting device according to the present invention;

FIG. 4 is a perspective view illustrating a conductive terminal of the second preferred embodiment;

FIG. 5 is a fragmentary perspective view of the third preferred embodiment of the light emitting device according to the present invention; and

FIG. 6 is a perspective view of the fourth preferred embodiment of the light emitting device according to the present invention.

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

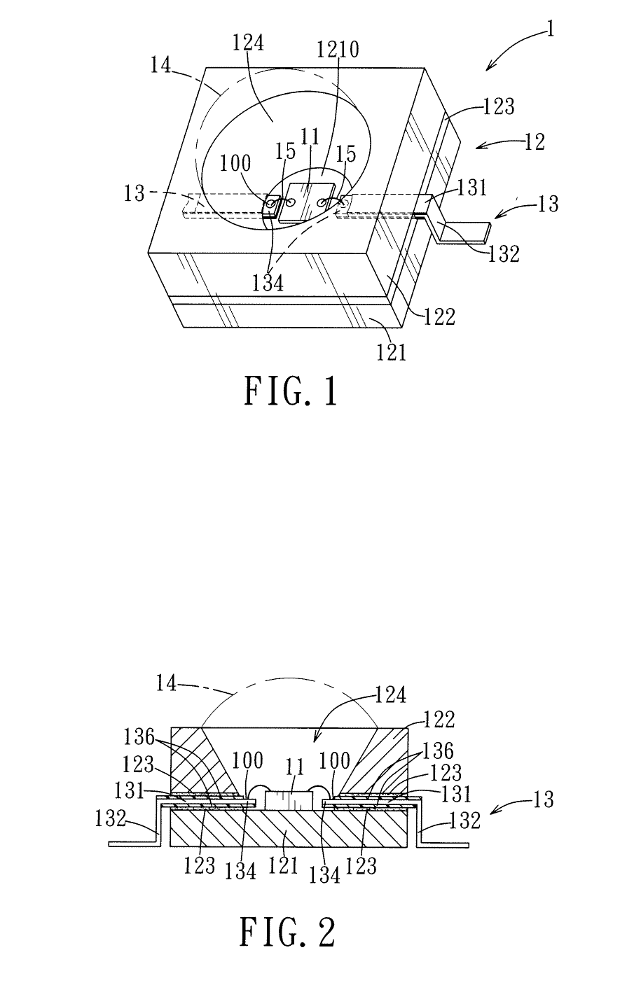

Referring to FIGS. 1 and 2, the first preferred embodiment of a light emitting device 1 according to the present invention is shown to include: a heat dissipating unit 12 including a metallic first heat sink 121 having a chip-mounting area 1210, a thermally conductive bonding layer 123, and a metallic second heat sink 122 overlapping and attached to the first heat sink 121 through the bonding layer 123, the heat dissipating unit 12 being formed with at least one light exit window 124 that is aligned with the chip-mounting area 1210 and that extends through the second heat sink 122 and the bonding layer 123 so as to expose the chip-mounting area 1210; at least one light emitting chip 11 attached to the chip-mounting area 1210 of the first heat sink 121 for emitting light through the light exit window 124; and a transparent enclosing material 14 filling the light exit window 124 to enclose the light emitting chip 11. In this embodiment, the light emitting chip 11 is a well known GaN on Al₂O₃ light emitting chip which has bonding pads of positive and negative electrodes formed on a top surface of the light emitting chip 11, and which is also called “two-pad chip”.

Note that the number of the light emitting chip 11 mounted on the chip-mounting area 1210 is not limited to one. The light emitting chip 11 may be attached to the first heat sink 121 in a conventional manner, such as using a silver paste, a transparent glue, an eutectic alloy, etc. Moreover, for enhancing light extraction efficiency, the chip-mounting area 1210 can be formed with a silver or gold reflecting layer thereon.

The transparent enclosing material 14 has a dome shaped portion protruding outwardly from the light exit window 124, and is preferably made from epoxy resin. Alternatively, the transparent enclosing material 14 can have a flat top portion, and can be made from silicone or glass. An inner wall of the second heat sink 122 that defines a funnel-shaped portion of the light exit window 124 can be formed with a highly reflective layer (not shown) for providing a light focusing effect. It is understood that the present invention can also be applied to a white light emitting package which can be formed using techniques known in the art, such as combining blue or UV light emitting chips with a suitable phosphors material.

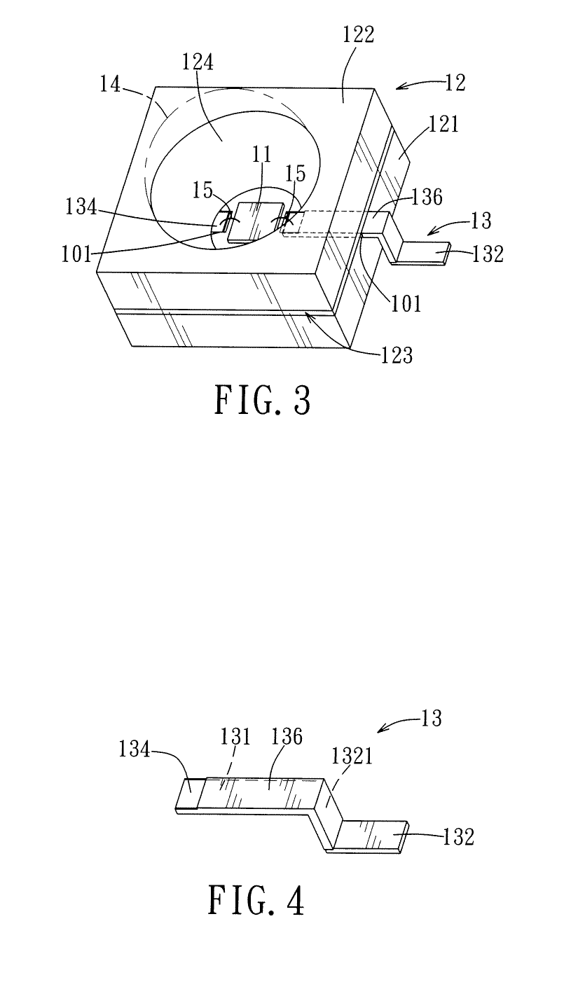

The light emitting device 1 further includes at least one pair of conductive terminals 13, each of which has an electrically insulated portion 131 and a connecting portion 134. The insulated portion 131 is disposed between the first and second heat sinks 121, 122, extends into the light exit window 124, and further extends outwardly beyond peripheral ends of the first and second heat sinks 121, 122. The connecting end portion 134 extends from one end of the insulated portion 131, and is connected directly to the light emitting chip 11 through a bonding wire 15. A bonding pad 100 is formed on the connecting end portion 134 of each of the conductive terminals 13. Each of the conductive terminals 13 further has an L-shaped tail portion 132 extending from the other end of the insulated portion 131 and spaced apart from the first and second heat sinks 121, 122. The conductive terminals 13 can be made from a metallic sheet with an insulator sleeve 136 sleeved on the insulated portion 131 of each of the conductive terminals 13 so as to prevent electric circuit shortage between the conductive terminals 13 and the first and second heat sinks 121, 122, as best shown in FIG. 3. The insulator sleeve 136 can be formed by plastic injection molding over the metallic sheet in a mold. It is understood that the positions and numbers of the conductive terminals 13 can varied according to actual requirements. Alternatively, each of the conductive terminals 13 is in the form of a flexible printed circuit strip.

In this embodiment, the first and second heat sinks 121, 122 and the bonding layer 123 are formed into a laminate such that the bonding layer 123 is sandwiched between and is bonded to the first and second heat sinks 121, 122. The bonding layer 123 is made from a good thermal conductive material, which can conduct the heat generated from the LED chip 11 through the first sink 121 to the second heat sink 122. The light exit window 124 has a funnel shape. For the purpose of easy production, the first and second heat sinks 121, 122 are generally rectangular in shape, and are preferably made from copper. Alternatively, the first and second heat sinks 121, 122 can be made from aluminum or other high thermal conductive materials. The bonding layer 123 is preferably made from a thermally conductive adhesive. Alternatively, the bonding layer 123 can be in the form of an adhesive tape, or made from a material selected from the group consisting of an eutectic alloy and a copper brazing alloy.

Optionally, the first and second heat sinks 121, 122 may be provided with heat dissipating fins so as to enhance heat dissipating efficiency thereof.

Referring to FIGS. 3 and 4, the second preferred embodiment of this invention differs from the previous embodiment in that one of the first and second heat sinks 121, 122 is formed with a pair of opposite recesses 101 (the recesses 101 are formed in the first heat sink 121 in this embodiment), each of which is in spatial communication with the light exit window 124. The insulated portion 131 of each of the conductive terminals 13 is embedded in a respective one of the recesses 101. The insulator sleeve 136 extends from the insulated portion 131 to a vertical segment 1321 of the L-shaped tail portion 132 so as to prevent electric circuit shortage between the L-shaped tail portion 132 and the first and second heat sinks 121, 122. Since each of the conductive terminals 13 is entirely received in the respective recess 101, the layer thickness of the bonding layer 123 can be reduced. Hence, the thermal conductivity between the first and second heat sinks 121, 122 can be improved.

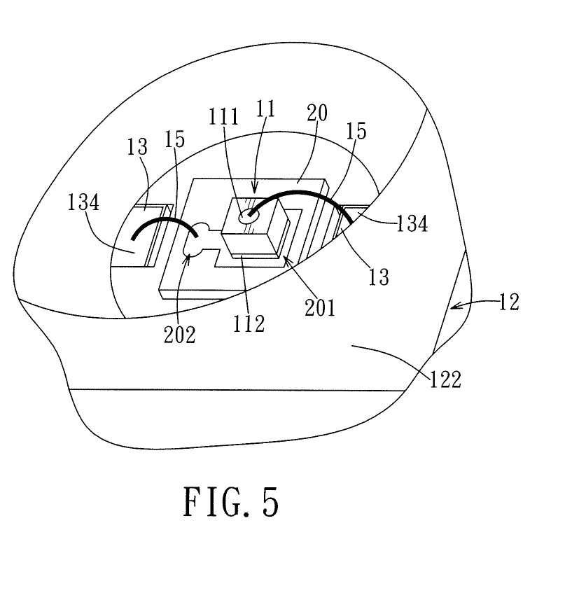

The following preferred embodiment illustrates how the heat dissipation scheme of this invention can also be used on different types of LED chips, such as vertical chips. The vertical LED chip has positive and negative electrodes formed on top and bottom surface of the LED chip. Referring to FIG. 5, the third preferred embodiment of the light emitting device 1 according to the present invention is a “vertical chip” which differs from the “two-pad chip” employed in the previous embodiments. In this embodiment, the light emitting chip 11 has an upper electrode 111 that is electrically connected to one of the conductive terminals 13 through a bonding wire 15, and a lower electrode 112 attached to a conductive pad 201 that is formed on a ceramic substrate 20 and that has an extension 202 which is electrically connected to the other of the conductive terminals 13 through another bonding wire 15.

The ceramic substrate 20 is electrically insulative between upper and lower surface thereof and is preferably made from a high thermal-conductive material, such as aluminum nitride or a silicon substrate. The conductive pad 201 is made by deposition with a metal layer thereon.

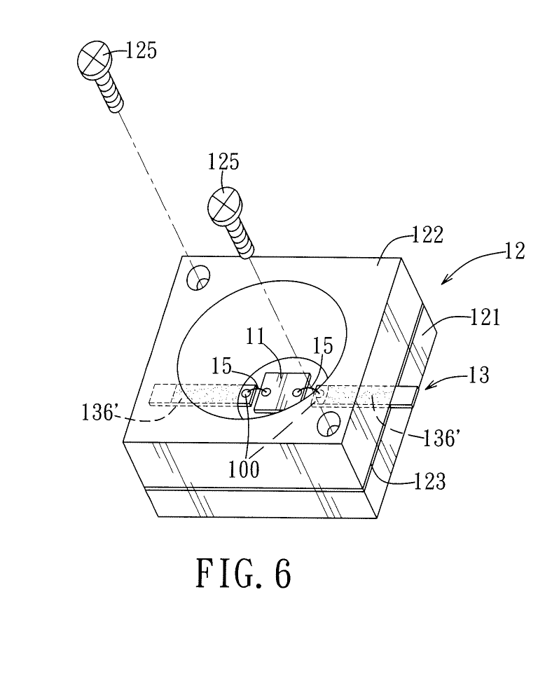

Referring to FIG. 6, the fourth preferred embodiment of the light emitting device 1 according to this invention differs from the previous embodiments in that, instead of using laminating techniques, the first and second heat sinks 121, 122 are fastened together using a pair of fastening screws 125, and that the bonding layer 123 is made from a thermally conductive paste. The fastening screws 125 extend through one of the first and second heat sinks 121, 122 to engage threadedly the other of the first and second heat sinks 121, 122. In this embodiment, each of the conductive terminals 13 is made from a single-layer printed circuit board. The printed circuit board of each of the conductive terminals 13 has a copper foil, a portion of which is covered with an insulator layer 136′ to avoid short circuit. A periphery of the junction between the first and second heat sinks 121, 122 is preferably sealed by a sealing material (not shown) for providing a water-proof property.

By overlapping and attaching a second heat sink 122 to the first heat sink 121 of the light emitting device of this invention, the heat dissipating efficiency of the heat dissipating unit 12 can be enhanced.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A light emitting device with heat-dissipating capability, comprising:
a heat dissipating unit including
a metallic first heat sink having a chip-mounting area,
a thermally conductive bonding layer, and
a metallic second heat sink overlapping and attached to said first heat sink through said bonding layer such that said bonding layer is sandwiched between said first and second heat sinks,
said heat dissipating unit being formed with at least one light exit window that is aligned with said chip-mounting area and that extends through said second heat sink and said bonding layer so as to expose said chip-mounting area;
at least one light emitting chip attached to said chip-mounting area of said first heat sink for emitting light through said light exit window;
at least one pair of electrically conductive terminals, each of which is coupled electrically to said light emitting chip and each of which has an insulated portion that is disposed between said first and second heat sinks and that extends outwardly beyond peripheral ends of said first and second heat sinks; and
a transparent enclosing material filling said light exit window to enclose said light emitting chip.

2. The light emitting device as claimed in claim 1, wherein each of said conductive terminals further has a connecting end portion that extends from said insulated portion, and that is connected directly to said light emitting chip.

3. The light emitting device as claimed in claim 2, wherein said insulated portion of each of said conductive terminals has a metallic sheet and a plastic material molded over said metallic sheet.

4. The light emitting device as claimed in claim 1, wherein each of said conductive terminals is in the form of a flexible printed circuit strip.

5. The light emitting device as claimed in claim 2, wherein said connecting end portion of each of said conductive terminals is electrically connected to said light emitting chip through a bonding wire.

6. The light emitting device as claimed in claim 1, wherein said first and second heat sinks and said bonding layer are formed into a laminate.

7. The light emitting device as claimed in claim 1, wherein said bonding layer is in the form of an adhesive tape.

8. The light emitting device as claimed in claim 1, wherein said bonding layer is made from a material selected from the group consisting of an eutectic alloy and a copper brazing alloy.

9. The light emitting device as claimed in claim 1, wherein said heat dissipating unit further includes at least one fastening screw extending through one of said first and second heat sinks to engage threadedly the other of said first and second heat sinks.

10. The light emitting device as claimed in claim 1, wherein said light exit window has a funnel shape.

11. The light emitting device as claimed in claim 1, wherein one of said first and second heat sinks is formed with a pair of opposite recesses, each of which is in spatial communication with said light exit window, each of said conductive terminals having an insulated portion that is embedded in a respective one of said recesses and that extends into said light exit window, and a connecting end portion that extends from said insulated portion, and that is connected directly to said light emitting chip.

12. The light emitting device as claimed in claim 11, wherein each of said conductive terminals is in the form of a printed circuit strip.
